(19) United States
(12) Patent Application Publication
(10) Pub. No.: US 2026/0064046 A1
(43) Pub. Date: Mar. 5, 2026

(54) IMAGE FORMING APPARATUS

(71) Applicant: CANON KABUSHIKI KAISHA, Tokyo (JP)

(72) Inventors: MASAKI SHIMOMURA, Shizuoka (JP); HIROYUKI SEKI, Shizuoka (JP); NOBUTOSHI SUGAI, Shizuoka (JP)

(21) Appl. No.: 19/310,487

(22) Filed: Aug. 26, 2025

(30) Foreign Application Priority Data
Aug. 28, 2024 (JP) 2024-146519

(51) Int. Cl. G03G 15/16; G01R 19/165; G03G 15/00; G03G 15/01

(52) U.S. Cl. CPC G03G 15/1615; G01R 19/1659; G03G 15/0131; G03G 15/0189; G03G 15/167; G03G 15/50; G03G 15/55

(57) ABSTRACT

An image forming apparatus includes a moving portion to perform a moving operation in which a transfer member is moved between a contact position where the transfer member contacts an image bearing member and a separated position where the transfer member is separated from the image bearing member. A detector detects a voltage applied to the transfer member and/or a current flowing through the transfer member when the voltage is applied to the transfer member. A discriminator discriminates whether a position of the transfer member is in the contact position or the separated position based on a result of comparison between a detecting result of the detecting portion and a reference value. The discriminator resets the reference value in a case in which the detecting result is not below the reference value while the moving operation of the moving portion is performed.

### BACKGROUND OF THE INVENTION

### Field of the Invention

The present invention relates to an image forming apparatus, such as a copier, a printer, and a fax machine using an electrophotographic method or an electrostatic recording method.

### Description of the Related Art

Conventionally, in the image forming apparatus using the electrophotographic method, etc., a transfer voltage is applied to a transfer member which contacts an image bearing member such as a photosensitive drum or an intermediary transfer belt and forms a transfer portion, and a toner image which is formed on the image bearing member is transferred to a transfer material. As the transfer member, a transfer roller which includes an elastic layer which is formed of an elastic member on a core metal is used. In such an image forming apparatus, when the image forming apparatus is left for a long term storage, etc. while the transfer member is kept contacting, local deformation may occur in the transfer member or the image bearing member due to pressure which is applied to a contacting portion (hereinafter, referred to as a contacting pressure). And depending on a degree of deformation, it may cause image defects due to transfer defects. Therefore, a configuration which separates the transfer member from the image bearing member or reducing the contacting pressure (hereinafter, referred to as a contacting/separating mechanism) may be provided with the image forming apparatus. In a case that such a contacting/separating mechanism is applied, a mechanism for detecting a position of the transfer member (hereinafter referred to as a contacting/separating state) is necessary. For example, in Japanese Laid-Open Patent Application (JP-A) 2001-083758, a configuration, which detects the position of the transfer member by detecting a current value which flows to the transfer member, is disclosed.

### SUMMARY OF THE INVENTION

In response to the above issue, the image forming apparatus according to the present invention includes configurations which will be described below.

An image forming apparatus comprising: an image bearing member configured to bear a toner image; a transfer member configured to form a transfer portion which transfers the toner image from the image bearing member to a transfer material in contact with the image bearing member; a moving portion configured to perform a moving operation in which the transfer member is moved between a contact position where the transfer member contacts the image bearing member and a separated position where the transfer member is separated from the image bearing member; a driving portion configured to drive the moving portion; an applying portion configured to apply a voltage to the transfer member; a detecting portion configured to detect at least one of a voltage applied to the transfer member by the applying portion and a current flowing through the transfer member when the voltage is applied to the transfer member by the applying portion; and a discriminating means configured to reset the reference value in a case in which the detecting result of the detecting portion is not below the reference value while the moving operation of the moving portion is performed.

Further features of the present invention will become apparent from the following description of exemplary embodiments with reference to the attached drawings.

### BRIEF DESCRIPTION OF THE DRAWINGS

FIG. 1 is a sectional view showing a schematic structure of an image forming apparatus according to a first embodiment, a second embodiment and a third embodiment.

FIG. 2 is a block diagram showing control modes of essential portions of the image forming apparatus according to the first embodiment, the second embodiment and the third embodiment.

Part (a) and part (b) of FIG. 3 are schematic diagrams illustrating operations of a secondary transfer contacting/separating mechanism according to the first embodiment, the second embodiment and the third embodiment.

FIG. 4 is a graph showing a detecting result of current value which is obtained during a contacting/separating operation in the first embodiment

FIG. 5 is a table showing relationships among absolute moisture content, applied voltage [V] and reference value in the first embodiment, the second embodiment and the third embodiment.

FIG. 6 is a flowchart showing a control in a conventional example which is compared with the first embodiment

FIG. 7 is a graph showing a result in which a current value is monitored when the contacting/separating operation is conducted in a dew condensation state in the first embodiment.

FIG. 8 is a flowchart showing a control of a contacting/separating operation in the first embodiment.

FIG. 9 is a graph showing a result in which a current value is monitored when the contacting/separating operation is conducted in a dew condensation state in the first embodiment.

FIG. 10 is a graph showing a result in which a current value is monitored when a gear is slipped in the first embodiment.

FIG. 11 is a flowchart showing a control of a contacting/separating operation in the second embodiment.

FIG. 12 is a graph showing a result in which a current value is monitored when the contacting/separating operation is conducted in a dew condensation state in the second embodiment.

FIG. 13 is a graph showing a detecting result of a current value which is obtained during a contacting/separating operation in the third embodiment.

FIG. 14 is a flowchart showing a control of a contacting/separating operation in the third embodiment.

FIG. 15 is a graph showing a result in which a current value is monitored when the contacting/separating operation is conducted in a dew condensation state in the third embodiment.

### DESCRIPTION OF THE EMBODIMENTS

In the following, an image forming apparatus according to the present invention will be described with reference to Figures.

### First Embodiment

### [1. Configuration of Image Forming Apparatus]

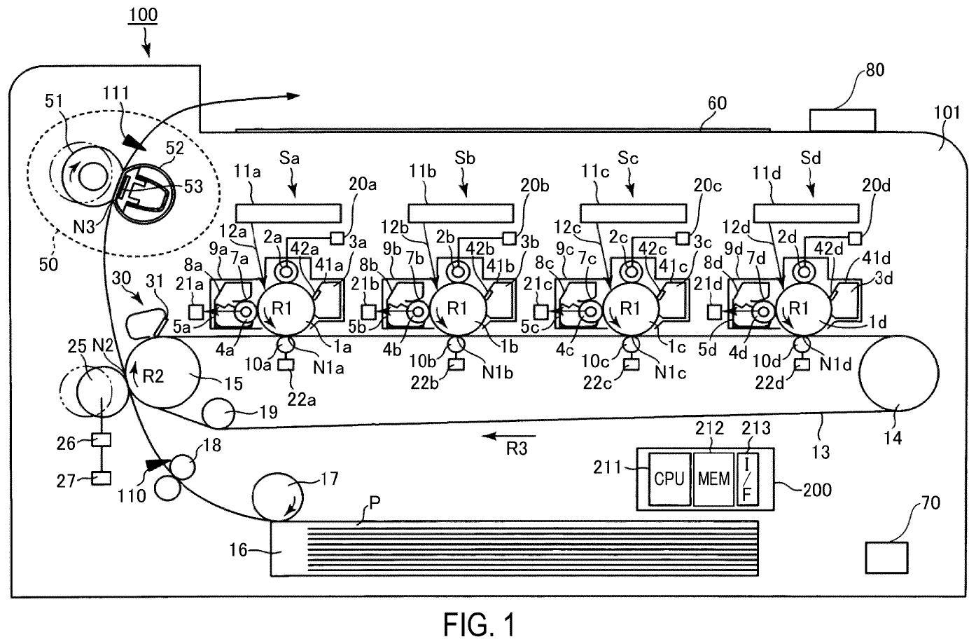

In the following, main configurations of the image forming apparatus 100 according to a first embodiment will be described below. FIG. 1 is a schematic sectional view of the image forming apparatus 100 according to the first embodiment. The image forming apparatus 100 according to the first embodiment is a tandem type printer (color image forming apparatus) which applies an intermediary transfer method, which is capable of forming a full color image by using an electrophotographic method.

The image forming apparatus 100 includes, as a plurality of image forming portions (stations), a first image forming portion Sa, a second image forming portion Sb, a third image forming portion Sc and a fourth image forming portion Sd which form images by using yellow (Y), magenta (M), cyan (C) and black (Bk) toners, respectively. The four image forming portions Sa, Sb, Sc and Sd are arranged in a row at substantially constant intervals along a moving direction of a surface of an intermediary transfer belt 13, which will be described below, to which an image is transferred. Incidentally, elements whose functions or configurations are the same as or corresponding to each color may be described collectively by omitting trailing letters of codes a, b, c, and d which indicate elements for any of the colors. In the first embodiment, the image forming portion S is configured to include a photosensitive drum 1, a charging roller 2, an exposure device 11, a developing device 8, a primary transfer roller 10, a cleaning device 3, etc., which will be described below.

An image forming portion S includes a photosensitive drum 1 which is a rotatable drum type (cylindrical) photosensitive member (electrophotographic photosensitive member) as a first image bearing member. The photosensitive drum 1 is configured so that a plurality of layers of functional organic materials, which are comprised of a carrier generating layer which generates an electric charge by being exposed to light and a charge transport layer which transports the generated electric charge, etc., are layered on a top of a cylindrical member which is made of metal. The photosensitive drum 1 is almost electrically insulated in its outermost layer, whose conductivity is low. The photosensitive drum 1 rotates in a direction of an arrow R1 (counterclockwise direction) in the figure at a predetermined peripheral speed (process speed) by receiving a driving force from a driving source (not shown).

The charging roller 2, which is a roller type charging member as a charging means, contacts the photosensitive drum 1 and is rotated in accordance with a rotation of the photosensitive drum 1. The charging roller 2 charges the surface of the photosensitive drum 1 in a substantially uniform manner, while rotating. The charging roller 2 is connected to a charging power source 20 as a charging voltage application portion. A DC voltage as a charging voltage is applied to the charging roller 2 from the charging power source 20. In this way, the surface of the photosensitive drum 1 is electrically charged by discharge which is generated in a microscopic gap between the charging roller 2 and the photosensitive drum 1 which is formed upstream and downstream of a contacting portion between the charging roller 2 and the photosensitive drum 1 with respect to a rotational direction of the photosensitive drum 1. The exposure device 11 as an exposure means is configured of a scanner unit which scans with laser light by a polygon mirror. The exposure device 11 irradiates the photosensitive drum 1 with a scanning beam 12 which is modulated based on an image signal.

The developing device 8 as a developing means includes a developer container 5, a developing roller 4 as a developing member, a blade 7 as a developer regulating member which applies a developer to the developing roller 4 and regulates a thickness of developer, and accommodates toner as a developer inside the developer container 5. The developing roller 4 is connected to a developing power source 21 as a developing voltage application portion. An alternating voltage which is superimposed with a DC voltage and an AC voltage as a developing voltage is applied to the developing roller 4 from the developing power source 21.

The cleaning device 3 as a cleaning means includes a cleaning blade 41 as a cleaning member which contacts the photosensitive drum 1, and a cleaning container 42 which accommodates a toner which is removed from the photosensitive drum 1 by the cleaning blade 41, etc. The cleaning device 3 collects the toner which is remained on the photosensitive drum 1. Incidentally, the photosensitive drum 1, the charging roller 2 as a process means which acts on the photosensitive drum 1, the developing device 8 and the cleaning device 3 configure a process cartridge 9 which is dismountable with respect to a main assembly 101 of the image forming apparatus 100.

The intermediary transfer belt 13, which is an intermediary transfer member which is configured of an endless belt as a second image bearing member, is arranged so as to oppose the photosensitive drum 1 of each image forming portion S. The intermediary transfer belt 13 is stretched by three stretching rollers, which are a secondary transfer opposing roller (hereinafter, simply referred to as an “opposing roller”) 15, a tension roller 14 and an auxiliary roller 19, as stretching members. The tension roller 14 is urged by a spring (not shown) as an urging member so as to maintain an appropriate tension of the intermediary transfer belt 13. The opposing rollers 15 rotates in a direction of an arrow R2 (clockwise direction) in the figure by receiving a driving force from a driving source (not shown). The intermediary transfer belt 13 moves peripherally (rotates) in a direction of an arrow R3 (clockwise direction) in the figure in accordance with the rotation of the opposing roller 15. The intermediary transfer belt 13 is possible to move in a forward direction at substantially the same speed as the photosensitive drum 1 at an opposing portion against the photosensitive drum 1. The auxiliary roller 19, the tension roller 14 and the opposing roller 15 are electrically grounded (connected to the earth). Incidentally, the opposing roller 15 is a roller whose outer diameter is 24.0 mm and is configured so that an elastic layer (elastic portion) which is formed of EPDM rubber whose thickness is 0.5 mm is covered around an aluminum core metal (base portion). An electric resistance value of the opposing roller 15 is adjusted so that the electric resistance value is approximately 110⁵Ω by dispersing carbon as a conductive agent in the EPDM rubber.

On an inner peripheral surface of the intermediary transfer belt 13, primary transfer rollers 10a, 10b, 10c and 10d which are roller type primary transfer members as primary transfer means, are arranged corresponding to photosensitive drums 1a, 1b, 1c and 1d, respectively. The primary transfer roller 10 is arranged in a position opposing the photosensitive drum 1 via the intermediary transfer belt 13, contacts the inner peripheral surface of the intermediary transfer belt 13 and is rotationally driven in accordance with the movement of the intermediary transfer belt 13. The primary transfer roller 10 contacts the photosensitive drum 1 via the intermediary transfer belt 13, is pressed against the photosensitive drum 1 and forms a primary transfer portion (primary transfer nip) N1 in which the photosensitive drum 1 and the intermediary transfer belt 13 contact. The primary transfer roller 10 is connected to a primary transfer power source 22 as a primary transfer voltage application portion. Incidentally, the primary transfer roller 10 is configured so that an elastic layer (elastic portion) which is formed of a foamed elastic material is covered around a core metal (base portion) which is formed of a nickel plating steel rod whose outer diameter is 5 mm and an outer diameter of the primary transfer roller is 14 mm. An electric resistance value of the primary transfer roller 10 is adjusted so that the electric resistance value is approximately 1×10⁶Ω by containing a conductive agent in the formed elastic material. It is preferable that the electrical resistance value of the primary transfer roller 10 is in a range of 10³Ω to 10⁷Ω in terms of performing favorable image formation.

On an outer peripheral surface of the intermediary transfer belt 13, a secondary transfer roller 25, which is a roller type secondary transfer member (transfer member) as a secondary transfer means, is arranged at a position opposing the opposing roller 15. The secondary transfer roller 25 is capable of contacting/separating with respect to the outer peripheral surface of the intermediary transfer belt 13. Incidentally, in FIG. 1, a state in which the secondary transfer roller 25 contacts the outer peripheral surface of the intermediary transfer belt 13 is indicated by a solid line, and a state in which the secondary transfer roller 25 is separated from the outer peripheral surface of the intermediary transfer belt 13 is indicated by a two dot chain line. The secondary transfer roller 25 is arranged in a position opposing the opposing roller 15 via the intermediary transfer belt 13, contacts the outer peripheral surface of the intermediary transfer belt 13, and is rotated in accordance with the movement of the intermediary transfer belt 13. The secondary transfer roller 25 contacts the opposing roller 15 via the intermediary transfer belt 13, is pressed against the opposing roller 15, and forms a secondary transfer portion (secondary transfer nip) N2 (transfer portion) in which the intermediary transfer belt 13 contacts the secondary transfer roller 25. The secondary transfer roller 25 is connected to a secondary transfer power source 26 as a secondary transfer voltage application portion (application portion). Further, the secondary transfer power source 26 is connected to a current detecting circuit 27 as a detecting portion. The secondary transfer power source 26 applies a voltage to the secondary transfer roller 25, and the current detecting circuit 27 is capable of detecting a current value which flows to the secondary transfer roller 25. Incidentally, the secondary transfer roller 25 is configured by covering an elastic layer (elastic portion) which is formed of a foamed elastic material around a core metal (base portion) which is made of metal.

A fixing device 50 as a fixing means includes a pressing roller 51 and a cylindrical fixing film (fixing belt) 52 as a fixing member (fixing rotatable member). A heating member 53 which applies heat to a transfer material P via the fixing film 52 is arranged on a side of the inner peripheral surface of the fixing film 52. The pressing roller 51 is capable of contacting/separating with respect to the outer peripheral surface of the fixing film 52. Incidentally, in FIG. 1, a state in which the pressing roller 51 contacts the outer peripheral surface of the fixing film 52 is indicated by a solid line, and a state in which the pressing roller 51 is separated from the outer peripheral surface of the fixing film 52 is indicated by a two dot chain line. The pressing roller 51 contacts the heating member 53 via the fixing film 52, is pressed against the heating member 53, and forms a fixing portion (fixing nip) N3 in which the pressing roller 51 contacts the fixing film 52. Further, the pressing roller 51 rotates by receiving a driving force from a motor as a driving source, and the fixing film 52 is rotated in accordance with the rotation of the pressing roller 51.

Further, the image forming apparatus 100 is provided with a control portion (control board, controller) 200 on which an electrical circuit for controlling an operation of each portion of the image forming apparatus 100 is mounted. A CPU 211 as a determining means, a memory 212 as a storage means for storing various control information, an input/output portion (I/F) 213 for controlling giving and receiving of a signal between the control portion 200 and each portion, etc. are mounted on the control portion 200. The CPU 211 executes control which is related to conveying the transfer material P, control which is related to driving the image forming portion S and the intermediary transfer belt 13, control which is related to image forming, control which is related to failure detection, etc. The memory 212 is configured to include a ROM (including a rewritable ROM) and a RAM, a program and a data table which are related to control, etc. are stored in the ROM and data which indicates detecting results of various sensors and a calculation result which is related to control, etc. are stored in the RAM.

The image forming apparatus 100 is provided with an environment sensor 70. The environment sensor 70 detects temperature and humidity as environmental information and outputs the detecting results to the control portion 200. The control portion 200 obtains an absolute moisture content which is based on the detecting results of the environment sensor 70. The image forming apparatus 100 is provided with an operation display portion 80. The operation display portion 80 includes a display device such as an LCD panel which informs a user of various information, and an input device such as a physical button and a touch panel of the LCD panel which receive an input operation from the user. The control portion 200 controls a display content of the display device by communicating with the operation display portion 80 and receives information which is input via the input device.

### [2. Image Forming Operation]

Next, an image forming operation of the image forming apparatus 100 according to the first embodiment will be described. When the control portion 200 receives an image signal from an external device (not shown), such as a personal computer, it starts an image forming operation. When the image forming operation starts, each photosensitive drum 1 and the opposing roller 15, etc., start rotating at a predetermined peripheral speed (process speed) by a driving force from a driving source (not shown). In the first embodiment, the process speed is 200 mm/s.

The surface of the rotating photosensitive drum 1 is uniformly charged by the charging roller 2. During a charging process, a charging voltage, which is a DC voltage which is the same polarity as a normal charging polarity (negative polarity in the first embodiment) of the toner, is applied to the charging roller 2 from the charging power source 20. The surface of the photosensitive drum 1 which is charged is scanned and exposed when the scanning beam 12, according to image information of a color component corresponding to each image forming portion S, is irradiated by the exposure device 11, and an electrostatic latent image (electrostatic image) according to the image information is formed on the photosensitive drum 1. The electrostatic latent image which is formed on the photosensitive drum 1 is developed (visualized) when the toner is supplied from the developing device 8, and a toner image (toner image, developer image) is formed on the photosensitive drum 1. In the developing device 8, the toner which is accommodated in the developer container 5 is charged to a negative polarity by the blade 7 and is applied to the developing roller 4. Further, during a developing process, a developing voltage which includes a DC component of the same polarity as the normal charging polarity (negative polarity in the first embodiment) of the toner is applied to the developing roller 4 from the developing power source 21. As a result, in a developing portion in which the developing roller 4 contacts the photosensitive drum 1, the toner is moved from the developing roller 4 to the image portion of the electrostatic latent image on the photosensitive drum 1 and adheres it. In the first embodiment, the toner which is charged to the same polarity as the charging polarity of the photosensitive drum 1 (negative polarity in the first embodiment) adheres to an exposed portion (image portion) whose absolute potential value is decreased by being exposed after being uniformly charged (reverse development). In the first embodiment, the normal charge polarity of the toner, which is the charge polarity of the toner at the time of development, is negative.

The toner image which is formed on the photosensitive drum 1 is transferred (primary transfer) to the intermediary transfer belt 13 which is rotated by an action of the primary transfer roller 10 at a primary transfer portion N1. During a primary transfer process, a primary transfer voltage, which is a DC voltage which is an opposite polarity (positive polarity in the first embodiment) to the normal charging polarity of the toner, is applied to the primary transfer roller 10 from the primary transfer power source 22. For example, during forming a full color image, each toner image of yellow, magenta, cyan, and black formed on each photosensitive drum 1 is primary transferred so that it is sequentially superimposed on intermediary transfer belt 13. As a result, four color toner images which are corresponding to an intended color image are formed on the intermediary transfer belt 13.

The toner image formed on the intermediary transfer belt 13 is transferred (secondary transfer) to the transfer material P, which is nipped and conveyed between the intermediary transfer belt 13 and the secondary transfer roller 25 by an action of the secondary transfer roller 25 at a secondary transfer portion N2. During a secondary transfer process, a secondary transfer voltage, which is a DC voltage which is an opposite polarity (positive polarity in the first embodiment) to the normal charging polarity of the toner, is applied to the secondary transfer roller 25 from the secondary transfer power source 26. The transfer material P (recording medium, recording material, sheet, paper) such as paper and OHP sheet is accommodated in a cassette 16. The transfer material P is fed from the cassette 16 to a conveying roller 18 by a feeding roller 17, and then conveyed to the secondary transfer portion N2 by the conveying roller 18.

The transfer material P to which the toner image transferred is conveyed toward the fixing device 50 by the secondary transfer roller 25 and the opposing roller 15. The fixing device 50 heats and presses the transfer material P at the fixing portion N3. The unfixed toner image which is borne on the transfer material P is fixed (melted, adhered) on the transfer material P when the transfer material P passes through the fixing portion N3. For example, during forming a full color image, the four colors of toner on the transfer material P are melted and mixed at the fixing portion N3 and fixed on the transfer material P. After that, the transfer material P is discharged (output) outside of the main assembly 101 of the image forming apparatus 100 and stacked on a discharge tray 60 as a stacking portion which is provided on an upper portion of the main assembly 101.

Incidentally, the image forming apparatus 100 is provided with a registration sensor 110, a discharge sensor 111, etc. as sensors for detecting the transfer material P during the image forming operation which is described above. On the other hand, the toner which is remained on the photosensitive drum 1 after the primary transfer (primary transfer residual toner), etc. are removed from the photosensitive drum 1 by the cleaning device 3 and collected. Further, a belt cleaning device 30 as an intermediary transfer member cleaning means is arranged at a position opposing the opposing roller 15 via the intermediary transfer belt 13 on an outer peripheral surface side of the intermediary transfer belt 13. The toner which is remained on the intermediary transfer belt 13 after the secondary transfer (secondary transfer residual toner), etc. are removed from the intermediary transfer belt 13 by the belt cleaning device 30 and collected. The belt cleaning device 30 is configured to include a cleaning blade 31 which contacts the outer peripheral surface of the intermediary transfer belt 13 at a position opposing the opposing rollers 15.

### [3. Control Mode]

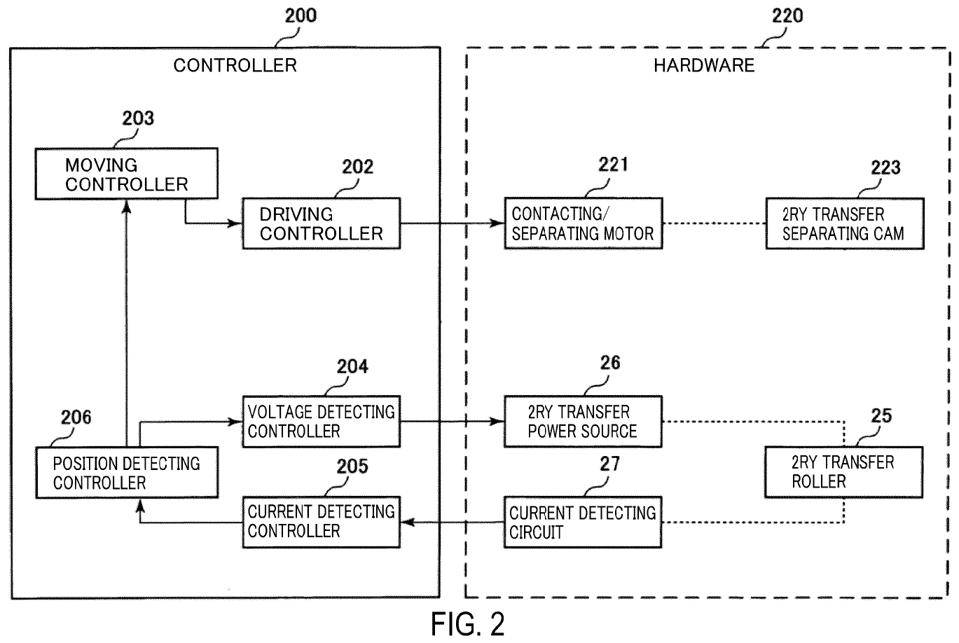

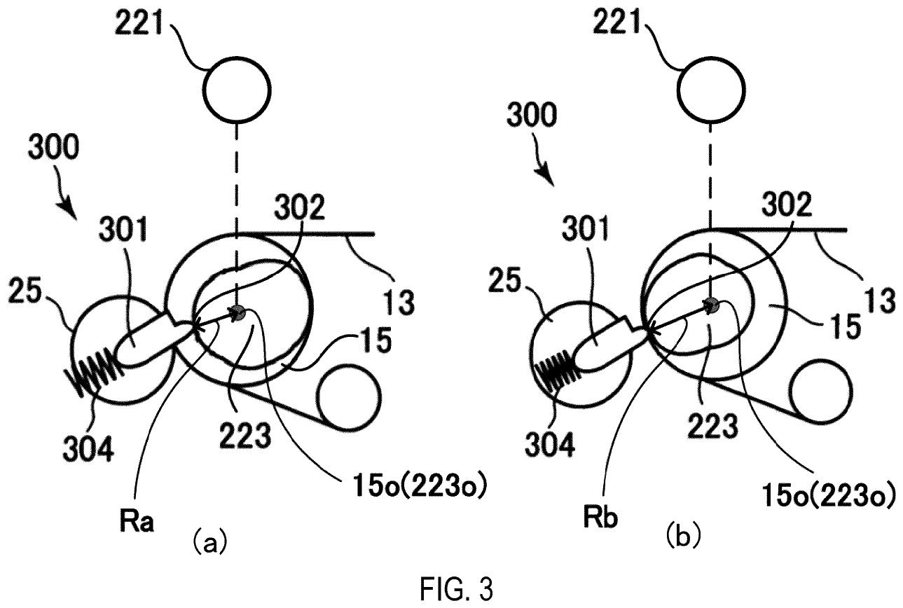

FIG. 2 is a block diagram showing a control mode for detecting (determining) a position of the secondary transfer roller 25 in the image forming apparatus 100 according to the first embodiment. FIG. 2 shows functional blocks in the control portion 200 and a hardware 220 which operates under a control of the control portion 200.

The control portion 200 includes a driving control portion 202, a moving control portion 203, a voltage control portion 204, a current detecting control portion 205 and a position detecting control portion 206, as the functional blocks. In the first embodiment, each functional block is realized when the CPU 211 (FIG. 1) executes a program which is stored in the memory 212 (FIG. 1) in the control portion 200. Further, in the control portion 200, the CPU 211, which realizes each functional block, controls an operation of the hardware 220 (including obtaining the detecting result) which is mainly shown in FIG. 2 via an input/output portion 213 (FIG. 1) and executes a process which is related to the detection of the position of the secondary transfer roller 25. The hardware 220 includes a contacting/separating motor 221, a secondary transfer separating cam 223, a secondary transfer roller 25, a secondary transfer power source 26 and a current detecting circuit 27.

When the moving control portion 203 drives the contacting/separating motor 221 as a driving portion by the driving control portion 202, the moving control portion 203 operates the secondary transfer separating cam 223 and moves the secondary transfer roller 25. That is, the moving control portion 203 changes the position of the secondary transfer roller 25 with respect to the intermediary transfer belt 13 (or the opposing roller 15). The secondary transfer separating cam 223, as a cam member which performs a moving operation to move the secondary transfer roller 25, configures a secondary transfer contacting/separating mechanism 300 (part (a) and part (b) of FIG. 3) which will be described below.

The position detecting control portion 206 detects the position of the secondary transfer roller 25 by actions of the voltage control portion 204, the current detecting control portion 205 and the moving control portion 203. That is, as will be specifically described below, the position detecting control portion 206 moves the secondary transfer roller 25 by the moving control portion 203, and the voltage control portion 204 applies voltage from the secondary transfer power source 26 to the secondary transfer roller 25. Then, the position detecting control portion 206 detects the position of the secondary transfer roller 25 based on the detecting result of the current value acquired by the current detecting control portion 205 from the current detecting circuit 27 when a voltage is applied to the secondary transfer roller 25.

Incidentally, in the first embodiment, the secondary transfer power source 26 is able to apply a voltage, which is controlled to be substantially constant at a voltage value (constant voltage control) which is set by the voltage control portion 204, to the secondary transfer roller 25. The voltage control portion 204 is able to detect (recognize) a voltage value of a voltage which is applied from the secondary transfer power source 26 to the secondary transfer roller 25 by the voltage value which is set for the secondary transfer power source 26. That is, in the first embodiment, the voltage control portion 204 is provided with a function of a voltage detecting portion which detects the voltage value of the voltage which is applied to the secondary transfer roller 25. The current detecting circuit 27 as a current detecting portion detects a current value which flows to the secondary transfer roller 25 when the secondary transfer power source 26 applies a voltage to the secondary transfer roller 25. The current detecting control portion 205 obtains the detecting result of the current value by the current detecting circuit 27. In the first embodiment, the secondary transfer power source 26 is able to apply a voltage which is controlled so that the current value detected by the current detecting circuit 27 becomes substantially constant (constant current control) to the secondary transfer roller 25.

### [4. Secondary Transfer Contacting/Separating Mechanism]

Next, the secondary transfer contacting/separating mechanism 300, as a moving portion which moves the secondary transfer roller 25 in the first embodiment to a plurality of positions with respect to the intermediary transfer belt 13, will be described. Part (a) and part (b) of FIG. 3 are schematic diagrams illustrating an operation of the secondary transfer contacting/separating mechanism 300. Part (a) of FIG. 3 indicates a contacting position in which the secondary transfer roller 25 contacts the intermediary transfer belt 13, and (b) of FIG. 3 indicates a separated position in which the secondary transfer roller 25 is separated from the intermediary transfer belt 13. Part (a) and part (b) of FIG. 3 are views of the secondary transfer roller 25 when they are viewed in a rotational axis direction of the secondary transfer roller 25 and one end portion side of the secondary transfer roller 25 with respect to the rotational axis direction is shown in each of part (a) and part (b) of FIG. 3, however, a configuration of the other end portion side is the same as the configuration which is shown in the figure (substantially symmetrical with respect to a center of the secondary transfer roller 25 in the rotational axis direction).

In the first embodiment, the secondary transfer contacting/separating mechanism 300 is configured with the secondary transfer separating cam 223, the contacting/separating motor 221, a bearing 301 of the secondary transfer roller 25, etc. The secondary transfer separating cam 223 is rotatably provided on both end portions of the opposing roller 15 with respect to the rotational axis direction. The secondary transfer separating cam 223 is rotatable around a rotational axis 2230 which is coaxial with a rotational axis 150 of the opposing roller 15. The bearing 301 of the secondary transfer roller 25 is provided on both end portions of the secondary transfer roller 25 with respect to the rotational axis direction and rotatably supports the secondary transfer roller 25. The bearing 301 of the secondary transfer roller 25 includes a contacting surface 302 which contacts the secondary transfer separating cam 223. The bearing 301 of the secondary transfer roller 25 is urged in a direction approaching the intermediary transfer belt 13 by a secondary transfer pressing spring 304 which is an urging member as an urging means.

When the contacting/separating motor 221 is rotated, the secondary transfer separating cam 223 rotates and it is possible to move the secondary transfer roller 25 to a target position with respect to the intermediary transfer belt 13. In the first embodiment, the secondary transfer separating cam 223 moves the secondary transfer roller 25 between a contacting position in which it contacts the intermediary transfer belt 13 and a separated position in which it is separated from the intermediary transfer belt 13. Incidentally, in the first embodiment, the secondary transfer separating cam 223 is configured to rotate in only one direction by the rotation of the contacting/separating motor 221.

As shown in part (a) of FIG. 3, when the secondary transfer roller 25 is in the contacting position in which it contacts the intermediary transfer belt 13, a distance between the contacting surface 302 and the rotational axis 2230 is a distance Ra. As shown in part (b) of FIG. 3, when the secondary transfer roller 25 is in the separated position in which it is separated from the intermediary transfer belt 13, a distance between the contacting surface 302 and the rotational axis 2230 is a distance Rb. Since the distance Rb is greater than the distance Ra (Ra<Rb), the secondary transfer contacting/separating mechanism 300 is capable of contacting and separating of the secondary transfer roller 25 by the rotation of the secondary transfer separating cam 223.

From a state in which the secondary transfer roller 25 is in the contacting position (part (a) of FIG. 3) in which it contacts the intermediary transfer belt 13, the contacting/separating motor 221 is rotated and the secondary transfer separating cam 223 is rotated by approximately 180 degrees. As a result, the bearing 301 of the secondary transfer roller 25 is retracted in a direction away from the intermediary transfer belt 13 when it is pushed by the secondary transfer separating cam 223, and the secondary transfer roller 25 moves to the separated position (part (b) of FIG. 3) in which it is separated from the intermediary transfer belt 13. Next, from a state in which the secondary transfer roller 25 is in the separated position in which it is separated from the intermediary transfer belt 13, the contacting/separating motor 221 is rotated and the secondary transfer separating cam 223 is rotated by approximately 180 degrees. As a result, the bearing 301 of the secondary transfer roller 25 moves in the direction approaching to the intermediary transfer belt 13, and the secondary transfer roller 25 returns to the contacting position (part (a) of FIG. 3) in which it contacts the intermediary transfer belt 13. That is, the secondary transfer separating cam 223 rotates once (one full rotation) from a state that the secondary transfer roller 25 contacts the intermediary transfer belt 13, the position of the secondary transfer roller 25 changes like, contacting to separating to contacting.

### [5. Relationship Between Position of the Secondary Transfer Roller and Current Value]

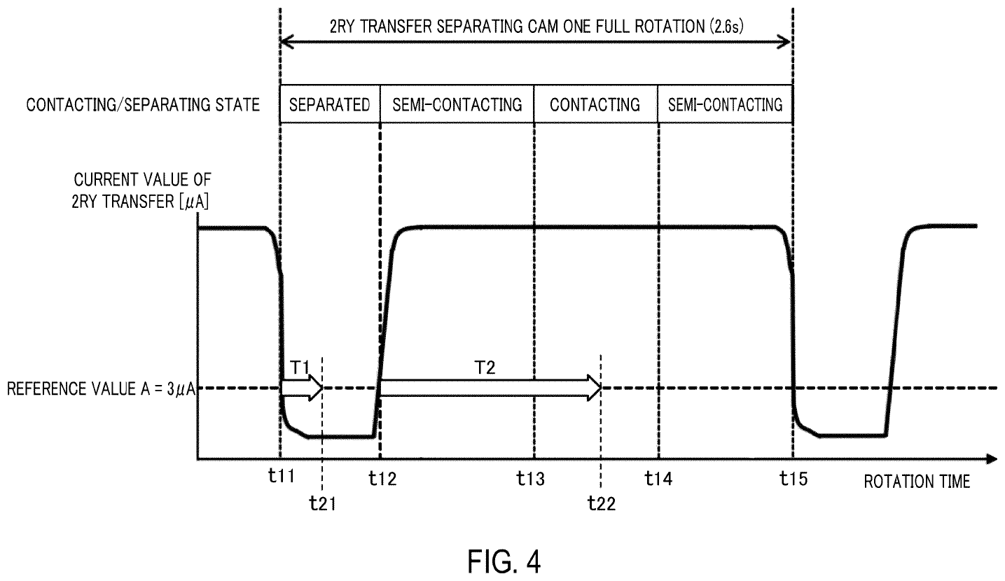

Next, with reference to FIG. 4, the relationship between the position of the secondary transfer roller 25 in the first embodiment and the detecting result of the current value which is obtained by the control portion 200 (current detection control portion 205) from the current detection circuit 27 will be described. FIG. 4 is a graph showing the detecting result of the current value which is obtained by the current detection control portion 205 from the current detection circuit 27 during the contacting/separating operation. In an upper part of FIG. 4, states of contacting/separating (separated, semi-contacting, contacting) of the secondary transfer separating cam 223 during one full rotation (rotating once). Further, in a lower part of FIG. 4, a graph, indicating a rotation time of the secondary transfer separating cam 223 on a horizontal axis and the current value (hereinafter, also referred to as a secondary transfer current value) [A] which is detected by the current detection circuit 27 on a vertical axis, is shown. Further, t11 to t15, t21, t22 indicate times. A reference value A (=3 μA) which will be described below is also shown as a dashed line on the current value graph in FIG. 4.

While the secondary transfer power source 26 applies a voltage to the secondary transfer roller 25 and the secondary transfer separating cam 223 is rotated, the current value becomes smaller at the separated position (time t11 to t12) in which the secondary transfer roller 25 is separated from the intermediary transfer belt 13. On the other hand, the current value becomes greater at the contacting position (time t13 to t14) in which the secondary transfer roller 25 contacts the intermediary transfer belt 13.

As contacting positions, there are two positions in which contacting pressures against the intermediary transfer belt 13 (or the opposing roller 15) of the secondary transfer roller 25 are different. Here, a position in which the contacting pressure is greater (a first contacting position) is simply referred to as “a contacting position,” and a position in which the contacting pressure is smaller (a second contacting position) is referred to as “a semi-contacting position.” There are also transitional states which are from the separated position to the contacting position and from the contacting position to the separated position, and the current value changes rapidly (time t11, t12, t15). In the first embodiment, it takes 2.6 seconds(s) for the secondary transfer separating cam 223 to make one full rotation. The voltage which is applied to the secondary transfer roller 25 from the secondary transfer power source 26 for detecting the position of the secondary transfer roller 25 is set as a DC voltage of a positive polarity.

### [6. Detection of Position of Secondary Transfer Roller]

Next, the detection (determination) of the position of the secondary transfer roller 25 by the control portion 200 (the position detecting control portion 206) in the first embodiment will be described. Here, in the first embodiment, detecting (determining) the position of the secondary transfer roller 25 means, more specifically, relating the position of the secondary transfer roller 25 (whether it is in the contacting position or the separated position) at a predetermined point in time (for example, at the present time). In the first embodiment, the position detecting control portion 206 detects the position of the secondary transfer roller 25 (whether it is in the contacting position or the separated position) based on the current value which flows to the secondary transfer roller 25.

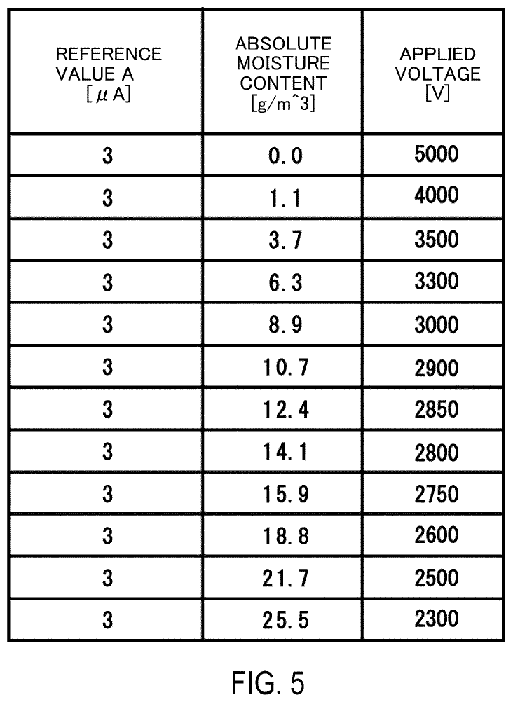

Specific figures will be described by using FIG. 5. FIG. 5 is a table showing relationships among a current value (reference value A) of 3 μA which is a threshold value for determining a contacting state or a separating state of the secondary transfer roller 25 of the image forming apparatus 100, an absolute moisture content [g/m³] in an installation environment and a voltage [V] which is applied to the secondary transfer roller 25. The voltage which is applied to the secondary transfer roller 25 is changed according to the installation environment of the image forming apparatus 100. Here, in a case that the absolute moisture content [g/m³] is between the values which are shown in FIG. 5, the value will be obtained by the linear interpolation. As shown in FIG. 5, when the reference value A is 3 μA, the secondary transfer power source 26 decreases the value of the voltage which is applied to the secondary transfer roller 25 as the absolute moisture content increases. For example, when the absolute moisture content is 1.1 g/m³, the applied voltage is set as 4000V, and when the absolute moisture content is 25.5 g/m³, the applied voltage is set as 2300V.

The control portion 200 controls the image forming operation based on a result of comparing the detecting result of the current detection circuit 27 with the reference value A. Specifically, the position detecting control portion 206 determines that it is at the separated position when the current value, which is obtained from the current detection circuit 27 during applying the voltage, is below the reference value A of 3 μA, and it is at the contacting position when the current value is above the reference value A of 3 μA. Normally, no current flows even when the voltage is applied during separation, however, since a dark current in the electrical circuit is estimated to be 1 μA±1 μA (0 to 2 μA), 3 μA is set as the threshold value (reference value A). When the current detection control portion 205 calculates the current value, it calculates an average current value, assuming that a sampling interval 2 [ms]×the number of sampling times 5[times] is regarded as one set.

### [7. Switching Control of Position of Secondary Transfer Roller]

In the first embodiment, the position detecting control portion 206 executes a following position switching operation to switch the position of the secondary transfer roller 25. The contacting position and the separated position are switched, by monitoring the current value while rotating the secondary transfer separating cam 223 which makes the secondary transfer roller 25 to contact and separate, and stopping the secondary transfer separating cam 223 after a predetermined time is elapsed from a timing at which the current value is switched.

Again, it will be described by using FIG. 4. The position detecting control portion 206 outputs a stop signal to the contacting/separating motor 221 after a first time T1, for example 100 ms, (time t21) is elapsed since a timing (time t11, t15) at which the current value which is obtained from the current detection circuit 27 is below the reference value A (=3 μA). The position detecting control portion 206 regards the stopped position as a completely separated position. Further, the position detecting control portion 206 outputs the stop signal to the contacting/separating motor 221 after a second time T2, for example 1000 ms, (time t22) is elapsed since a timing (time t12) at which the current value which is obtained from the current detection circuit 27 is above the reference value A (=3 μA). The position detecting control portion 206 regards the stopped position as a completely contacting position. The control portion 200 determines that it is at the contacting position when the first time T1 is elapsed from the timing when the detecting result of the current detection circuit 27 is below the reference value A, and that it is at the contacting position when the second time T2 is elapsed from the timing when the detecting result is above the reference value A. A waiting time for the contacting/separating motor 221 to stop after receiving the stop signal is expected to be 20 ms. What is described above is a procedure that the image forming apparatus 100 detects the position of the secondary transfer roller 25 in a normal condition. Here, the normal condition means a condition in which dew condensation does not occur.

[8. Contacting/Separating Behavior in Conventional Example when Dew Condensation is Generated on the Secondary Transfer Roller 25]

Next, a contacting/separating behavior in a conventional example when dew condensation occurs on the secondary transfer roller 25, which is an object of the present invention, will be described. As described above, when trying to detect the position of the secondary transfer roller 25 by detecting the current value which flows to the secondary transfer roller 25 in a state that dew condensation is occurred on the secondary transfer roller 25, the current value which is detected becomes greater since the electrical resistance value is smaller than in a normal state. Therefore, even though in fact it is separated, an erroneous detection that it is contacting may occur.

First of all, dew condensation is formed on the secondary transfer roller 25. As a method, the image forming apparatus 100 is installed in an environmental test chamber at 5° C. and 80% humidity and is left for 12 hours or more. After that, the environmental test chamber is changed to 25° C. and 60% humidity over a period of 60 minutes. A temperature in the environmental test chamber rises rapidly, however, members such as the secondary transfer roller 25 in the image forming apparatus 100, whose heat capacity is large, rise in temperature slowly, so difference between the temperature in the environmental test chamber and the temperature the members is occurred. As a result, heated air is cooled on the surface of the members, and water droplets are generated on the surface of the members.

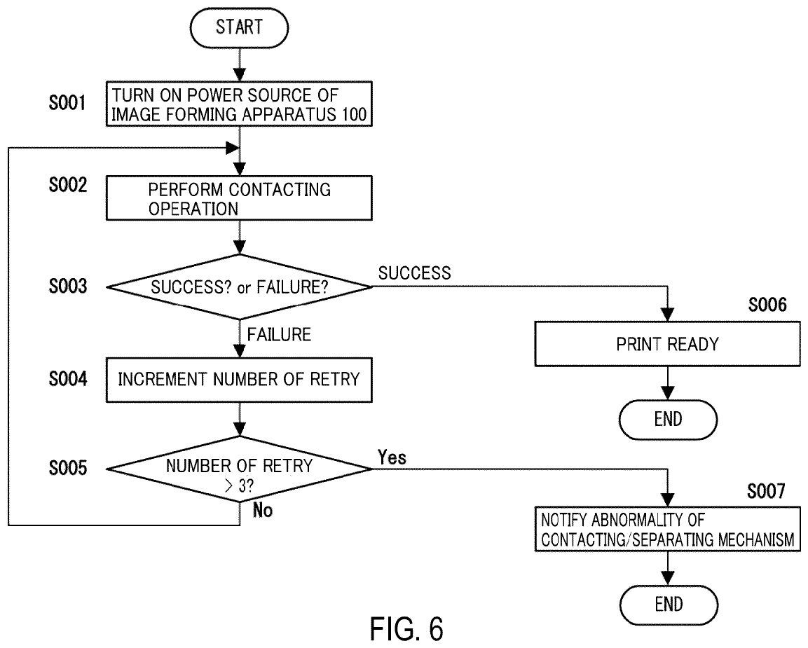

A control in the conventional example will be described by using the flowchart in FIG. 6. In a step (hereinafter referred to as S) 001, the image forming apparatus 100 is turned on (ON) in a dew condensation state. Incidentally, the control portion 200 resets a counter to zero, which counts the number of retries which will be described below. In S002, the control portion 200 enters an operation of contacting the secondary transfer roller 25, whose contacting position or separated position is unknown (hereinafter referred to as an undefined state). Incidentally, the control portion 200 resets and starts a timer (not shown) in order to control the time elapsed since the rotation of the secondary transfer separating cam 223 is started. Here, when the power source of the image forming apparatus 100 is turned off (OFF), the secondary transfer roller 25 should be in the separated state. However, since there is a possibility that the secondary transfer separating cam 223 is rotated and a phase is shifted while the power source of the image forming apparatus 100 is turned off, or that the secondary transfer roller 25 is missed, an operation of contacting of S002 is performed when the power source is turned on.

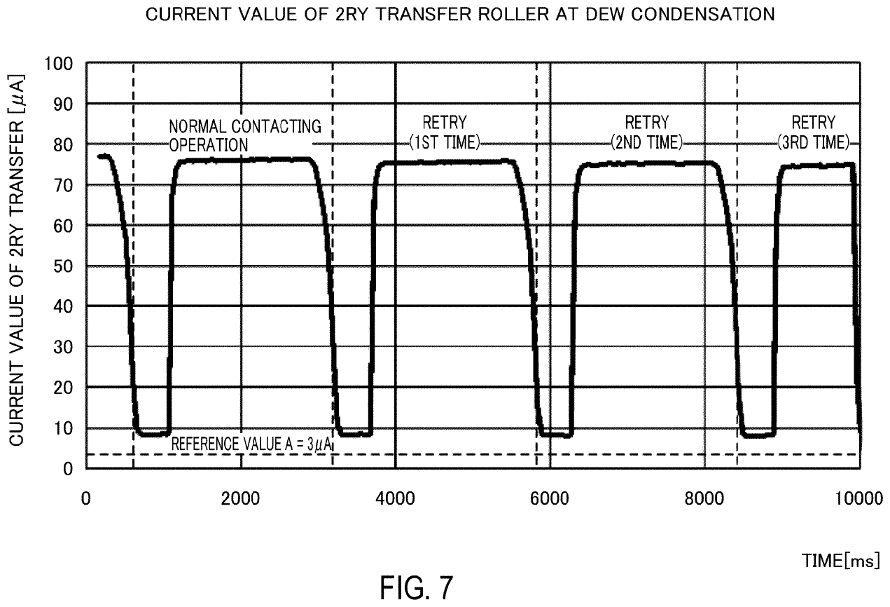

FIG. 7 is a graph showing a result of monitoring the current value while rotating the secondary transfer separating cam 223 which contacts and separates the secondary transfer roller 25 actually in a state that dew condensation is occurred on the secondary transfer roller 25. In the graph in FIG. 7, the time [ms] is on a horizontal axis, and the current value [A] which flows to the secondary transfer roller 25 is on a vertical axis. Further, in FIG. 7, the reference value A (=3 μA) is shown by a dashed line.

Since the installation environment of the image forming apparatus 100 is 25° C. in temperature and 60% in humidity, the absolute moisture content is 12.0 [g/m³] and the voltage which is applied to the secondary transfer roller 25 is calculated as 2860V by linear interpolation from FIG. 5. The control portion 200 rotates the secondary transfer separating cam 223 while applying the voltage (2860V) to the secondary transfer roller 25. Under a normal condition, the secondary transfer separating cam 223 is rotated, the stop signal is output to the contacting/separating motor 221 after 1000 ms (time t22 in FIG. 4) elapsed since the timing when the current value is above the reference value A (=3 μA) (time t12 in FIG. 4), and the secondary transfer roller 25 is set to the contacting position. However, the current value is increased when dew condensation is occurred on the secondary transfer roller 25, and the current value is not below the reference value A (=3 μA) even when it is separated, so there is no timing at which the current value intersects and exceeds 3 μA. For example, in an example shown in FIG. 7, even though the secondary transfer roller 25 is actually moved from the separated position to the contacting position, the detected current value always exceeds 3 μA. In this case, it is not possible to calculate the timing for outputting the stop signal to the contacting/separating motor 221 in order to contact the secondary transfer roller 25.

In S003, the control portion 200 determines whether the operation of contacting is succeeded or not. In S003, in a case that the control portion 200 determines that the operation of contacting is succeeded, it proceeds to S006, and in S006, the image forming apparatus 100 becomes in a print ready state in which it is possible to print, and the process is terminated. In S003, in a case that the control portion 200 determines that the operation of contacting is failed, it proceeds to S004.

In the case of FIG. 7 as described above, the operation of contacting is failed. Here, the control portion 200 performs a retry in a case that the current value is not below 3 μA even when the secondary transfer separating cam 223 is rotated for 2.6 s, in which the secondary transfer separating cam 223 makes one full rotation by referring to the timer. That is, the control portion 200 rotates the secondary transfer separating cam 223 again and performs the contacting/separating operation of S002. Since it takes 2.6 s for the secondary transfer separating cam 223 to make full one rotation, a time period of the current detection is also set to 2.6 s and a retry time is optimized. In S004, before entering the retry, the control portion 200 adds one (+1) to the number of retries which is managed by the counter. Incidentally, in FIG. 7, the number of retries is reached to a predetermined number, for example, three times.

In S005, the control portion 200 determines whether the number of retries is greater than three. In S005, in a case that the control portion 200 determines that the number of retries is greater than three, it proceeds to S007. In S007, the control portion 200 notifies a user of a failure of the secondary transfer contacting/separating mechanism 300 (contacting/separating mechanism abnormality information). In S005, in a case that the control portion 200 determines that the number of retries is three or less, it returns the process to S002 and enters the retry operation.

In a case that the current value is below 3 μA even after three times of retries as shown in FIG. 7, the control portion 200 determines that the contacting/separating mechanism of the secondary transfer roller 25 is not operating normally such that the secondary transfer separating cam 223 is damaged or the contacting/separating motor 221 is out of order. The control portion 200 interrupts activation of the image forming apparatus 100 and informs the user of the contacting/separating mechanism failure via the operation display portion 80. However, in the example which is shown in FIG. 7, a waveform of the current value which is detected is similar to a waveform during normal operation, and, in fact, no failure is occurred. In the example which is shown in FIG. 7, the current which flows to the secondary transfer roller 25 is increased simply due to an effect of dew condensation. In this case, for example, by leaving the image forming apparatus 100 for another 60 minutes or so, the dew condensation is eliminated and the operation of contacting is completed as normal. That is, in case of a conventional control, incorrect information is informed to the user.

[9. Contacting/Separating Behavior According to the First Embodiment when Dew Condensation is Generated on the Secondary Transfer Roller 25]

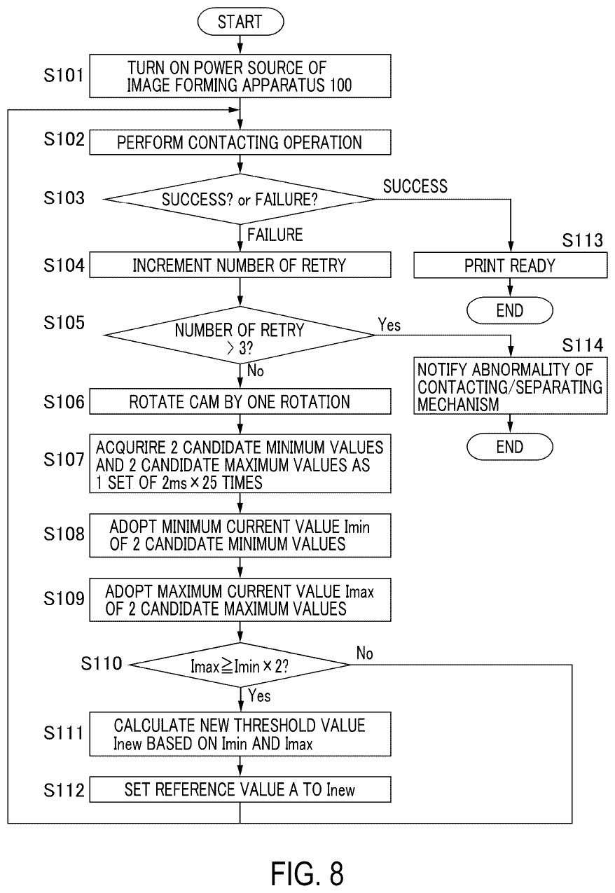

A method for detecting the contacting/separating state even when dew condensation occurs on the secondary transfer roller 25, which is a feature of the present invention, will be described by using a flowchart in FIG. 8. Incidentally, the processes of from S101 through S105, S113 and S114 in FIG. 8 are the same as those of from S001 through S007 in FIG. 6, therefore the descriptions will be omitted.

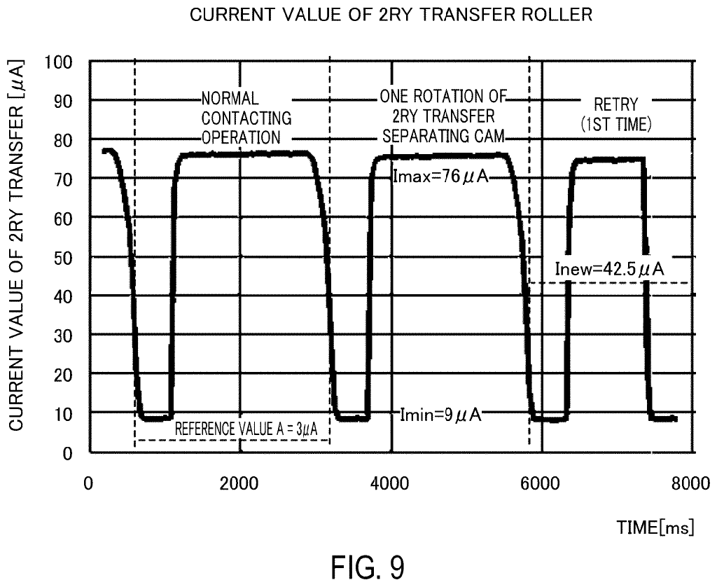

Here, in a state that dew condensation is in fact generated on the secondary transfer roller 25, a result of monitoring the current value, while rotating the secondary transfer separating cam 223 which contacts and separates the secondary transfer roller 25 under a control according to the first embodiment, is shown in FIG. 9. FIG. 9 is a graph similar to FIG. 7. When the operation of contacting is succeeded, the image forming apparatus 100 becomes in a print ready state, however, the current value which is detected is not below the reference value A (=3 μA) due to dew condensation even when it is separated in FIG. 9, so the operation of contacting is failed (S103: failure). In a case that the number of retries is less than three, the control portion 200 enters the retry operation after S106 by a determination in S105. In the first embodiment, the control portion 200 obtains a plurality of current values which flow to the secondary transfer roller 25 by the current detection circuit 27 during one full rotation of the secondary transfer separating cam 223, and obtains a maximum current value and a minimum current value. This will be specifically described below.

In S106, the control portion 200 rotates the secondary transfer separating cam 223 (shown simply as “cam” in the figure) by one full rotation. In S107, the control portion 200 calculates an average value of the current values which are sampled (hereinafter referred to as an average current value) when a sampling interval of 2 [ms]×the number of sampling times 25 [times] is regarded as one set. The control portion 200 obtains two candidate minimum values and two candidate maximum values from the average current values which are calculated. Here, the reason why the number of samples is greater than when calculating the average current value in a case that dew condensation is not occurred as described above, is to increase an accuracy of the average value. In S108, the control portion 200 excludes a smaller one of the two minimum value candidates which is obtained in S107 as a noise and adopts a remaining one as a minimum current value Imin. In S109, the control portion 200 excludes a larger one of the two maximum value candidates which is obtained in S107 as a noise and adopts a remaining one as a maximum current value Imax.

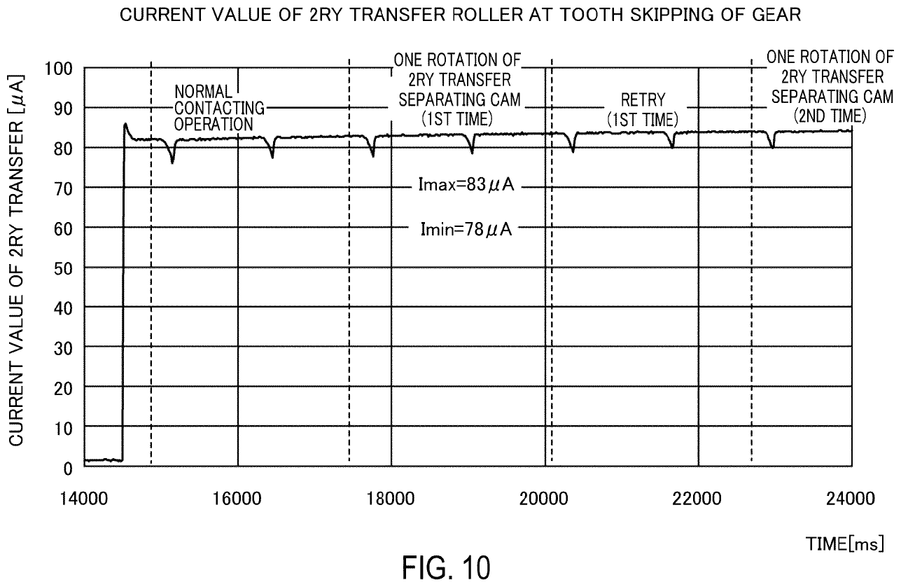

In S110, the control portion 200 determines whether the maximum current value Imax is greater than or equal to the minimum current value Imin×2. Here, a purpose of the determination in S110 will be described by using FIG. 9 and FIG. 10. As shown in FIG. 9, in a state that dew condensation is generated, an overall current value becomes greater, and although the current value which is detected is not below the reference value A (=3 μA), the current value which is detected fluctuates greatly when contacting and separating the secondary transfer roller 25. A purpose of the determination in S110 is to detect a timing of contacting/separating by utilizing the large fluctuation. When the current value in case of contacting (maximum current value Imax) is two times or more than the current value in case of separating (minimum current value Imin), it is possible to determine that the contacting/separating mechanism of the secondary transfer roller 25 is operated normally and the overall current value is increased only due to dew condensation. Incidentally, in a case that the contacting/separating mechanism is not, in fact, operated normally as described below, since the maximum current value (Imax) and the minimum current value (Imin) are almost same, it is possible to distinguish sufficiently when a multiplication is 2 or more and 2 is multiplied.

In FIG. 9, the maximum current value Imax in a first rotation of the secondary transfer separating cam 223 is 76.0 μA (S108), and the minimum current value Imin is 9.0 μA (S109). The maximum current value Imax of 76.0 μA is greater than 18.0 μA, which is twice the minimum current value Imin of 9.0 μA. In this case, the control portion 200 determines that the contacting/separating mechanism of the secondary transfer roller 25 is operated normally and the overall current value is increased only due to dew condensation (S110 Yes).

In a case that the control portion 200 determines that the maximum current value Imax is smaller than the minimum current value Imin×2 in S110, it returns the process to S102 while the reference value A is kept at the same value (3 μA), in other words, the reference value A is not reset. In this case, the control portion 200 determines that the contacting/separating mechanism is not operating normally and performs a retry again in a conventional manner. And in a case that the control portion 200 determines that the number of retries is three or more in S105, it informs the user of the contacting/separating mechanism failure in S114. The control portion 200 informs that the secondary transfer separating cam 223 is abnormal in a case that the number of times, that the detecting result which is detected by the current detecting circuit 27 during moving operation which is performed by the secondary transfer separating cam 223 is not below the reference value A, exceeds a predetermined number.

Here, the detecting result of the current is shown in FIG. 10 in a case that the gear which rotates the secondary transfer separating cam 223 is slipped and the secondary transfer separating cam 223 does not rotate so the contacting/separating mechanism does not operate normally. FIG. 10 is similar to FIG. 7. In this case, since dew condensation is generated on the secondary transfer roller 25, the overall current value greatly exceeds the reference value A (=3 μA). The current value does not fluctuate significantly, since the secondary transfer separating cam 223 does not rotate even when the contacting/separating motor 221 is driven in a condition that the voltage is applied to the secondary transfer roller 25. In FIG. 10, the maximum current value Imax is 83.0 μA, the minimum current value Imin is 78.0 μA and the multiplication is approximately 1.06. In a case that the maximum current value Imax of 83.0 μA is less than 156.0 μA which is twice the minimum current value Imin of 78.0 μA (S110 No), the control portion 200 determines that the contacting/separating mechanism is not operating normally.

FIG. 8 will be described again. In S110, the control portion 200 resets the reference value A in a case that a following conditional expression is satisfied.

Conditional expression: Imax≥Imin×predetermined value That is, in a case that the control portion 200 determines that the maximum current value Imax is greater than or equal to the minimum current value Imin×2, it proceeds to S111. The control portion 200 calculates a current value Inew as a new threshold value (new threshold), which is a threshold value for determining the contacting state or the separating state of the secondary transfer roller 25, based on the maximum current value Imax and the minimum current value Imin. The control portion 200 resets the reference value A so that it is smaller than the maximum current value and greater than the minimum current value among the current values flowing to the secondary transfer roller 25 which is detected by the current detection circuit 27 when the moving operation of the secondary transfer roller 25 is performed. In the first embodiment, the current value Inew=(Imax+Imin)/2. For example, in an example of FIG. 9, (76.0 μA+9.0 μA)/2=42.5 μA. In S112, the control portion 200 stores the current value Inew (new threshold value) which is calculated in S111 in the memory 212 of the image forming apparatus 100, sets that the reference value A=Inew and returns the process to S102. In this way, when the moving operation of the secondary transfer roller 25 by the secondary transfer separating cam 223 is performed, in a case that the detecting result which is detected by the current detecting circuit 27 is below the reference value A (from S102 through S103, failure), the control portion 200 resets the reference value A (from S106 through S112).

In an example of FIG. 9, the control portion 200 returns the process to S102 again, rotates the secondary transfer separating cam 223 while applying the voltage to the secondary transfer roller 25 and enters the retry of the operation of contacting. At this time, the control portion 200 applies the current value (reference value A) which is the threshold value for determining the contacting state or the separating state of the secondary transfer roller 25, not an initial value of 3 μA, but the current value Inew=42.5 μA which is reset in S112. Since only a few seconds is elapsed since a previous operation of contacting which is shown in FIG. 9, a state of the dew condensation of the secondary transfer roller 25 is not changed significantly, and a current waveform of a first retry is similar to last time. A difference from the last time is that the current value (reference value A) as the threshold value for determining the contacting state or the separating state of the secondary transfer roller 25 is updated from 3 μA to 42.5 μA. Therefore, when the current value is below 42.5 μA, the control portion 200 determines that the secondary transfer roller 25 is in the separated position. This is the difference from the last time. The control portion 200 rotates the secondary transfer separating cam 223 from a state that the secondary transfer roller 25 is separated, and outputs a stop signal to the contacting/separating motor 221 at 1000 ms after a timing at which the current value is above the threshold value of 42.5 μA, and a position in which it is stopped becomes the contacting position. In this way, the operation of contacting is succeeded.

A method for detecting the contacting/separating state even when dew condensation is generated on the secondary transfer roller 25, which is a feature of the present invention, is described above.

In the first embodiment, the present invention is described by using the color image forming apparatus, however, it is not limited to this, and a monochrome image forming apparatus may also be used. Incidentally, in the embodiment, as the method for calculating the average current value, the sampling interval of 2 [ms]×the number of sampling times 25 [times] is regarded as one set, however, it is not limited to this, and it may be changed in accordance with the image forming apparatus which is used. Further, in order to eliminate noise, the maximum value and the minimum value of the average current values which are calculated are excluded, however, this may be changed according to a configuration. Further, it is described that it is determined that the contacting/separating mechanism is operating normally when the maximum current value Imax is greater than or equal to the minimum current value Imin×2, however, this may also be changed according to a configuration, and the value may be such that it is possible to determine whether the contacting/separating mechanism is operating normally or not. That is, a predetermined value which is multiplied by the minimum current value Imin may be any integral number of 2 or more. Further, the average value is calculated from the maximum current value Imax and the minimum current value Imin, and it is defined as the current value Inew, which is the new threshold value for determining the contacting state or the separating state of the secondary transfer roller 25, however, this may also be changed according to a configuration. Further, in the first embodiment, in order to describe easily, it is described as a flow that in a case that the minimum current value Imin is not below the reference value A during the operation of contacting for the first time, the secondary transfer separating cam 223 is rotated for one full rotation, the reference value A is replaced with Inew, and the operation of contacting is performed as a retry. However, it may calculate Inew from the operation of contacting for the first time without rotating the secondary transfer separating cam 223 for one full rotation, and as far as the calculation of Inew is completed in time, it may perform the operation of contacting for the first time instead of the retry. Furthermore, the detecting portion is not limited to the current detecting circuit 27 which detects the secondary transfer current, however, it may be anything which detects at least one of the secondary transfer current and the voltage which is applied to the secondary transfer roller 25. Furthermore, the control of the first embodiment is applicable as far as a member which performs contacting and separating and a member which determines the contacting and separating state by the voltage detection or the current detection, and embodiments as follows are similar to this.

As described above, according to the first embodiment, it is possible to detect the position of the transfer member accurately even when dew condensation is generated on the transfer member.

### Second Embodiment

[10. Contacting/Separating Behavior According to the Second Embodiment when Dew Condensation is Generated on the Secondary Transfer Roller 25]

A second embodiment of the present invention will be described. In the second embodiment, a calculation method of the current value Inew, which is the new threshold value for determining the contacting state or the separating state of the secondary transfer roller 25 when dew condensation is generated, is different. In the second embodiment, instead of calculating the current value Inew from the maximum current value Imax and the minimum current value Imin, the current value Inew is determined by stepwisely (gradually) changing the value in a case that retry is repeated a plurality of times. Incidentally, issues which are not specifically described in the second embodiment are similar to those in the first embodiment and the descriptions will be omitted.

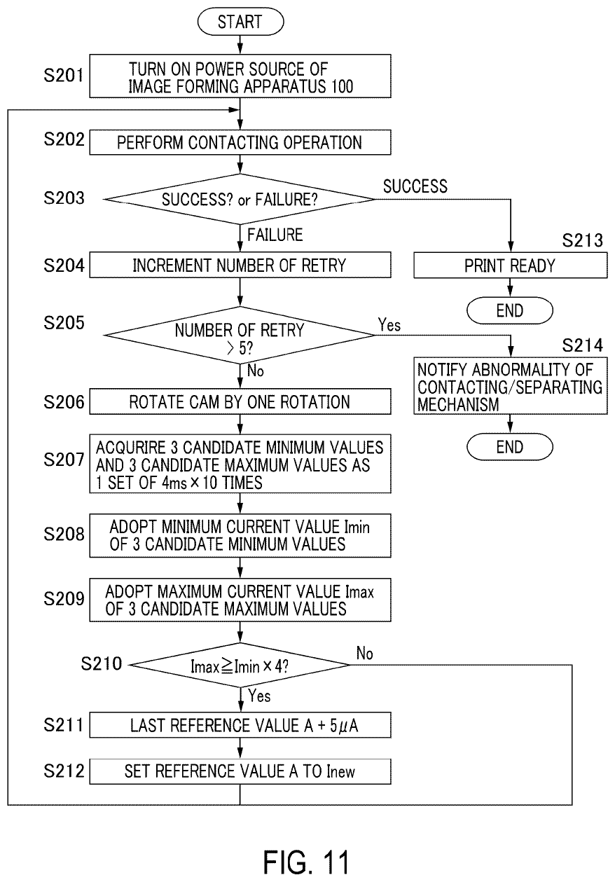

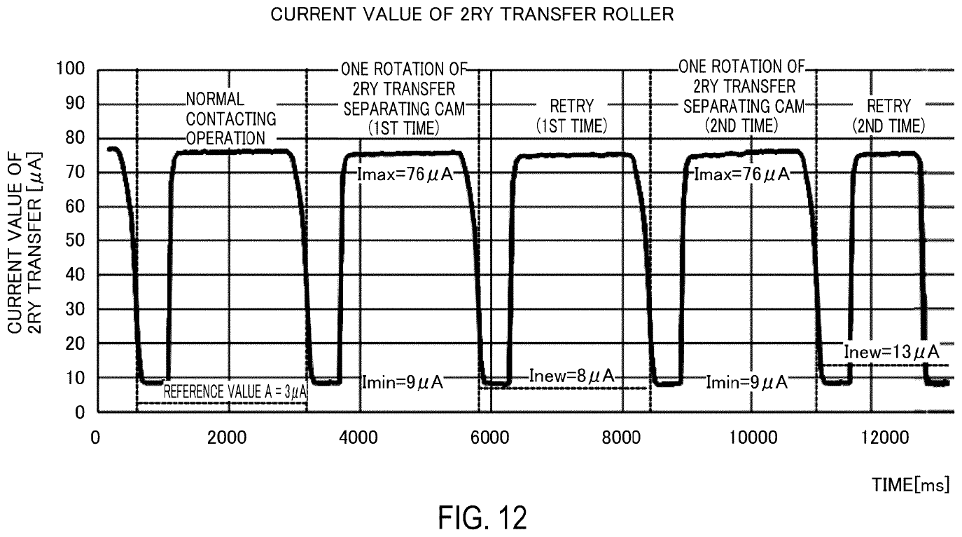

It will be described by using a flowchart in FIG. 11. Incidentally, the processes of S201 through S204, S206 and S212 through S214 are similar to the processes of S101 through S104, S106 and S112 through S114 in FIG. 8, and the descriptions will be omitted. Here, in a state that dew condensation is generated on the secondary transfer roller 25, results of monitoring the current value while rotating the secondary transfer separating cam 223 which contacts and separates the secondary transfer roller 25 under the control of the second embodiment are shown in FIG. 12. A horizontal axes and a vertical axes of FIG. 12 are similar to those of FIG. 9.

The control portion 200 determines whether the number of retries is greater than five in S205, when it determines that the current value which is detected is not below the reference value A (=3 μA) and the operation of contacting and separating is failure due to dew condensation even in a case it is separated. In a case that the control portion 200 determines that the number of retries is more than five in 205, it informs the user of the contacting/separating mechanism failure in S214. In a case that the control portion 200 determines that the number of retries is five or less in S205, it enters a retry operation and rotates the secondary transfer separating cam 223 for one full rotation in S206.

In S207, the control portion 200 calculates an average current value assuming that a sampling interval 4 [ms]×the number of sampling times 10 [times] is regarded as one set, and obtains three minimum value candidates and three maximum value candidates. In S208, the control portion 200 excludes smaller two of the three minimum value candidates as noises and adopts a remaining one as the minimum current value Imin. In S209, the control portion 200 excludes larger two of the three maximum value candidates as noises and adopts a remaining one as the maximum current value Imax.

In S210, the control portion 200 determines whether the maximum current value Imax is greater than or equal to the minimum current value Imin×4. For example, in FIG. 12, the maximum current value Imax is 76.0 μA and the minimum current value Imin is 9.0 μA, and the maximum current value Imax of 76.0 μA is greater than the minimum current value Imin of 9.0 μA×4=36.0 μA. In this case, the control portion 200 determines that the contacting/separating mechanism of the secondary transfer roller 25 is operated normally and the overall current value is increased only due to dew condensation.

In a case that the control portion 200 determines that the maximum current value Imax is greater than or equal to the minimum current value Imin×4, it proceeds to S211. The control portion 200 calculates the current value Inew as the new threshold value for determining the contacting state or the separating state of the secondary transfer roller 25. In a case that the detecting result of the current detecting circuit 27 is not below the reference value A, the control portion 200 resets the reference value A to a value in which a predetermined value is added to the reference value A in the second embodiment. For example, the current value Inew (=8 μA) is calculated by adding a predetermined value, 5 μA in this case, to the initial reference value A (=3 μA). In S212, the control portion 200 stores the current value Inew which is calculated in S211 in the memory 212 of the image forming apparatus 100. Therefore, the reference value A=Inew.

The control portion 200 returns the process to S202 again, rotates the secondary transfer separating cam 223 while applying the voltage to the secondary transfer roller 25 and enters the retry of the operation of contacting. At this time, the control portion 200 applies the current value (reference value A) which is the threshold value for determining the contacting state or the separating state of the secondary transfer roller 25, not the initial value of 3 μA, but the current value A Inew=8 μA which is reset in S212.

Since only a few seconds is elapsed since a operation of contacting at the last time in an example of FIG. 12, a state of the dew condensation of the secondary transfer roller 25 is not changed significantly, and the current waveform is similar to previous one. A difference from the last time is that the current value (reference value A) as the threshold value for determining the contacting state or the separating state of the secondary transfer roller 25 is updated from 3 μA to 8 μA. However, since the minimum current value Imin is not below 8 μA even in a first retry, a second retry is performed. In S211 before the second retry, the control portion 200 adds 5 μA to Inew=8 μA which is used in the first retry and defines the new reference value A as 13 μA, and the control portion 200 resets the reference value A as 13 μA in S212 and returns the process to S202. In the second retry, since the minimum current value Imin is below Inew=13 μA, the control portion 200 determines that the secondary transfer roller 25 is separated (S203, Success). The control portion 200 rotates the secondary transfer separating cam 223 from a state in which the secondary transfer roller 25 is separated, and outputs the stop signal to the contacting/separating motor 221 1000 ms after a timing at which the current value is above the threshold value of 13 μA. And the position in which it is stopped becomes the contacting position and the operation of contacting is succeeded. In a case that the detecting result of the current detecting circuit 27 is not below the reference value A repeatedly, the control portion 200 resets the reference value A so that the reference value A stepwisely becomes greater.

Incidentally, the method of adding 5 μA to the initial value of 3 μA for each retry is described as the method of calculating the current value Inew in the embodiment, however, it is not limited to the method and it may be changed according to the image forming apparatus which is used. Further, the Inew which is calculated is stored in the memory 212 as the reference value A, however, it may be reset to the initial value of 3 μA each time the contacting/separating operation is succeeded.

As described above, according to the second embodiment, even when dew condensation is generated on the transfer member, it is possible to detect the position of the transfer member accurately.

### Third Embodiment

A third embodiment of the present invention will be described. In the third embodiment 3, a method for detecting the contacting/separating state of the secondary transfer roller 25 when it is recovered from dew condensation will be described. The method for detecting the contacting/separating state of the secondary transfer roller 25, when dew condensation is eliminated and a resistance of the secondary transfer roller 25 is returned to a normal condition after the contacting/separating operation of the secondary transfer roller 25 is succeeded during dew condensation in the second embodiment, will be described.

Since the current value is not below the reference value of 3 μA due to dew condensation during the contacting/separating operation, a control is conducted such that the predetermined 5 μA is added to the reference value of 3 μA and the current value Inew is calculated in the second embodiment. The contacting/separating operation is succeeded in the second retry in which the current value Inew=13 μA, and the image forming apparatus 100 became in a print ready state. However, in a case that the current value Inew=13 μA which is calculated is stored in the memory 212, 13 μA will be used as the reference value A next time when the contacting/separating operation is performed. In a case that dew condensation is eliminated at this point, the current value may not become greater than 13 μA in some cases, and in that case, it is not possible to detect the contacting/separating state.

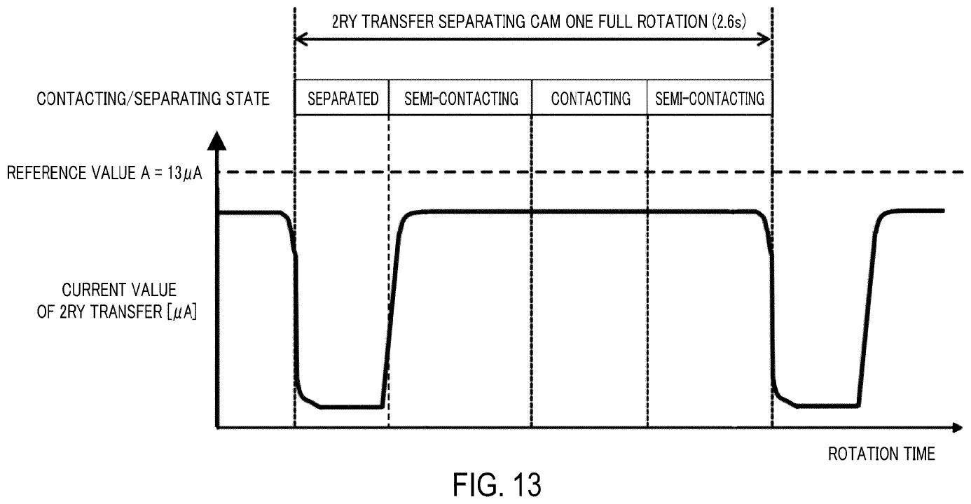

It will be described by using FIG. 13. FIG. 13 is a graph showing the detecting result of the current value in which the current detecting control portion 205 obtains from the current detecting circuit 27 during the contacting/separating operation, which is similar to FIG. 4. A difference from FIG. 4 is that the current value (reference value A) as the threshold value for determining the contacting state or the separating state of the secondary transfer roller 25 is not the initial value of 3 μA but 13 μA. In this case, since the current value does not become greater than 13 μA, it is not possible to calculate the timing for outputting the stop signal to the contacting/separating motor 221 for contacting the secondary transfer roller 25. Therefore, in the third embodiment, a method, for detecting the contacting/separating state by stepwisely decreasing the reference value A during the retries in a case that the current value is not above the reference value A, will be described.

[11. Contacting/Separating Behavior According to the Third Embodiment when Dew Condensation is Generated on the Secondary Transfer Roller 25]

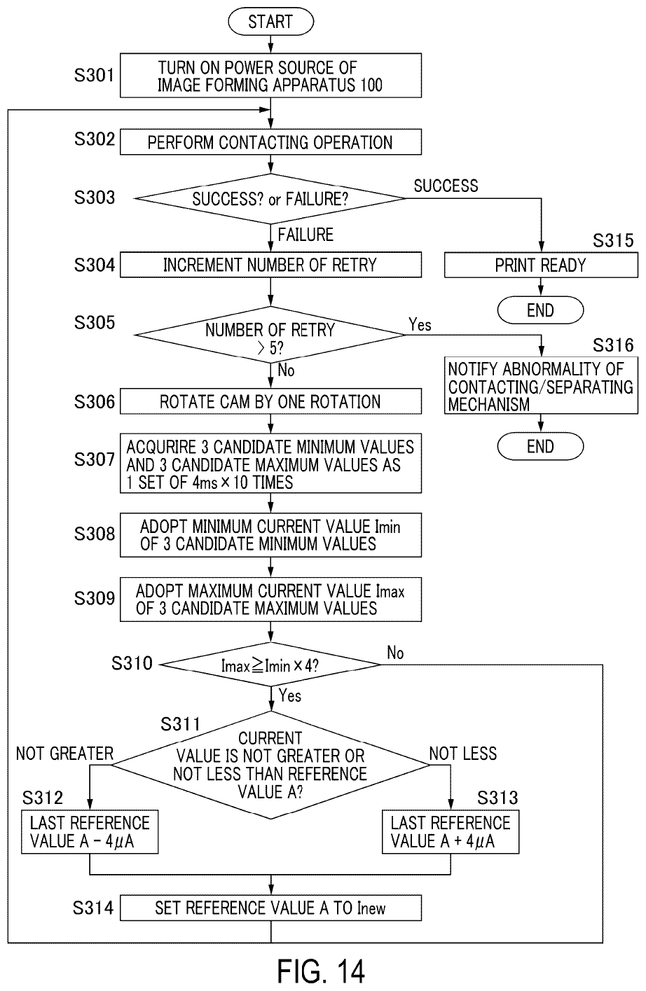

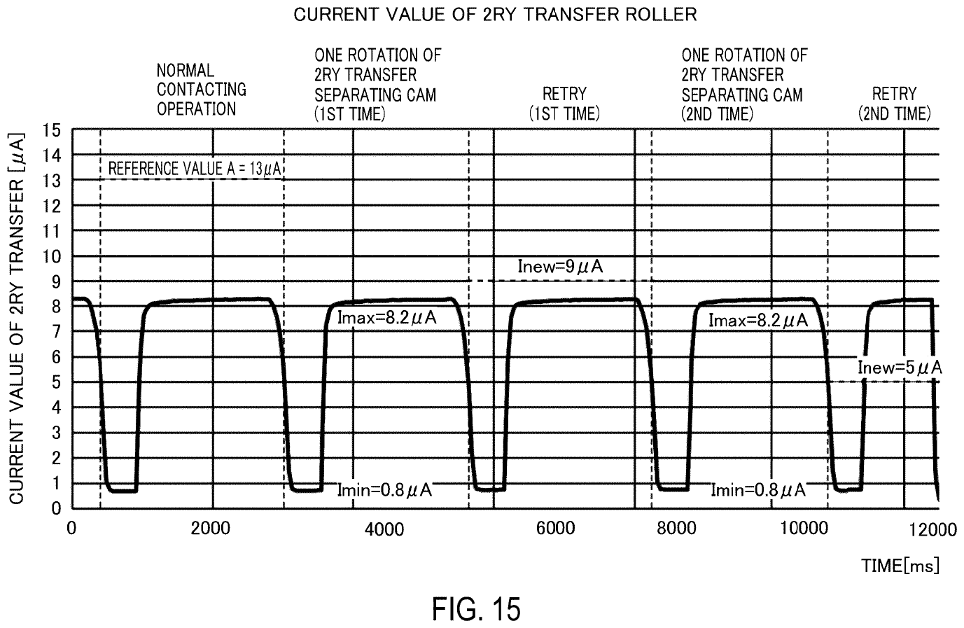

Incidentally, issues which are not specifically described in the third embodiment are similar to those in the first embodiment and the second embodiment and the descriptions will be omitted. It will be described by using a flowchart in FIG. 14. Incidentally, the processes of S301 through S310, S314 through S316 are similar to the processes of S201 through S210, S212 through S214 in FIG. 11, and descriptions will be omitted. Further, results of monitoring the current value while rotating the secondary transfer separating cam 223 which, in fact, contacts and separates the secondary transfer roller 25 under the control of the third embodiment are shown in FIG. 15. A horizontal axes and a vertical axes of FIG. 15 are similar to those of FIG. 12.

When the operation of contacting is succeeded (S303, success), the image forming apparatus 100 becomes in the print ready state that it is possible to print (S315), however, in FIG. 15, the current value is not above the reference value A of 13 μA even when it is contacting, it is failed (S303: failure). When the number of retries is less than five (S305, No), the control portion 200 enters the retry operation after S306.

In S310, the control portion 200 determines whether the maximum current value Imax is greater than or equal to the minimum current value Imin×4. In FIG. 15, the maximum current value Imax is 8.2 μA and the minimum current value Imin is 0.8 μA, and the maximum current value Imax of 8.2 μA is greater than the minimum current value Imin of 0.8 μA×4=3.2 μA. In this case, the control portion 200 determines that the contacting/separating mechanism of the secondary transfer roller 25 is operated normally and the overall current value is increased only due to dew condensation and it proceeds to S311.

In S311, the control portion 200 determines whether the maximum current value Imax does not become greater than the reference value A or whether the minimum current value Imin does not become less than the reference value A. In a case that the maximum current value Imax does not become greater than the reference value A, the control portion 200 proceeds to S312. In S312, the control portion 200 adjust to make the reference value A smaller. In a case that the detecting result of the current detecting circuit 27 is not above the reference value A, the control portion 200 resets the reference value A to a value in which a predetermined value is subtracted from the reference value A, and it proceeds to S314. For example, the control portion 200 subtracts 4 μA from a reference value A at the last time (A−4 μA). On the other hand, in a case that the minimum current value Imin is not below the reference value A, the control portion 200 proceeds to S313. In S313, the control portion 200 adjusts to make the reference value A greater. In a case that the detecting result of the current detecting circuit 27 is not below the reference value A, the control portion 200 resets the reference value A to the value in which the predetermined value is added to the reference value A and it proceeds to S314. For example, the control portion 200 adds 4 μA to the reference value A at the last time (A+4 μA).

In FIG. 15, the maximum current value Imax is 8.2 μA in the first rotation of the secondary transfer separating cam 223, and it is not above the reference value of 13 μA. In the third embodiment, the control portion 200 subtracts a predetermined value, which is 4 μA in this case, from the initial reference value A of 13 μA, and calculates the current value Inew=13 μA−4 μA=9 μA (S311).

In S314, the control portion 200 stores the current value Inew which is calculated in S312 or S313 in the memory 212 of the image forming apparatus 100, and it sets the reference value A=Inew. For example, in the case of FIG. 15, the reference value A is 9 μA. The control portion 200 returns the process to S302 again, and while the voltage is applied to the secondary transfer roller 25, it rotates the secondary transfer separating cam 223 and enters the operation of contacting.

In an example of FIG. 15, the control portion 200 applies the current value Inew=9 μA which is calculated in S312 as the current value (reference value A) which is the threshold value for determining the contacting state or the separating state of the secondary transfer roller 25, instead of the initial value of 13 μA. Since only a few seconds is elapsed since a operation of contacting at the last time which is shown in FIG. 15, the state of the dew condensation of the secondary transfer roller 25 is not changed significantly, and the current waveform is similar to previous one. A difference from the last time is that the current value (reference value A) as the threshold value for determining the contacting state or the separating state of the secondary transfer roller 25 is updated from 13 μA to 9 μA. However, since the maximum current value Imax is not above 9 μA even in the first retry, the second retry is performed. Further, 4 μA is subtracted from the current value Inew=9 μA at the first retry, and it becomes 5 μA. In the second retry, the maximum current value Imax is above Inew=5 μA, so it is determined that the secondary transfer roller 25 is contacted. In a case that the detecting result of the current detecting circuit 27 is not above the reference value A repeatedly, the control portion 200 resets the reference value A so that the reference value A stepwisely becomes smaller. The control portion 200 outputs the stop signal to the contacting/separating motor 221 1000 ms after the timing at which the current value which is detected is above the reference value A (5 μA). Therefore, the position in which it is stopped becomes the contacting position and the operation of contacting is succeeded.

Incidentally, the method of subtracting 4 μA from the initial value of 13 μA for each retry is described as the method of calculating the current value Inew in the embodiment, however, it is not limited to the method and it may be changed according to the image forming apparatus which is used. Furthermore, a fixed value (4 μA) is subtracted in S312 of FIG. 14, and the fixed value (4 μA) is added in S313, however, the value which is subtracted or added is not limited to the fixed value, and, for example, the value which is subtracted or added may change each time the reference value A is set. In a case that the detecting result is not above the reference value A repeatedly, the control portion 200 may reset the reference value A so as to be greater or smaller than the reference value which is set at the last time.

As described above, according to the third embodiment, even when dew condensation is generated on the transfer member, it is possible to detect the position of the transfer member accurately.

### OTHER EMBODIMENTS

It is possible to realize the present invention by supplying a program which realizes one or more functions of the embodiments which are described above to a system or a device via a network or a storage medium, and reading and executing the program with one or more processors in a computer of the system or the device. Further, it is possible to realize by a circuit (for example, ASIC) which realizes one or more functions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-146519, filed on Aug. 28, 2024, which is hereby incorporated by reference herein in its entirety.

What is claimed is:

1. An image forming apparatus comprising:
an image bearing member configured to bear a toner image;
a transfer member configured to form a transfer portion which transfers the toner image from the image bearing member to a transfer material in contact with the image bearing member;
a moving portion configured to perform a moving operation in which the transfer member is moved between a contact position where the transfer member contacts the image bearing member and a separated position where the transfer member is separated from the image bearing member;
a driving portion configured to drive the moving portion;
an applying portion configured to apply a voltage to the transfer member;
a detecting portion configured to detect at least one of a voltage applied to the transfer member by the applying portion and a current flowing through the transfer member when the voltage is applied to the transfer member by the applying portion; and
a discriminating means configured to reset the reference value in a case in which the detecting result of the detecting portion is not below the reference value while the moving operation of the moving portion is performed.

2. The image forming apparatus according to claim 1, wherein in a case in which the detecting portion detects the current flowing through the transfer member, the discriminating means resets the reference value so as to be smaller than a maximum current value and be larger than a minimum current value, of values of current flowing through the transfer member detected by the detecting portion while performing the moving operation.

3. The image forming apparatus according to claim 1, wherein when a case in which the detecting result is not below the reference value is repeated a plurality of times, the discriminating means resets the reference value so as to be larger than the reference value set at the last time.

4. The image forming apparatus according to claim 1, wherein in a case in which the detecting result is not below the reference value, the discriminating means resets a value obtained by adding a predetermined value to the reference value as the reference value.

5. The image forming apparatus according to claim 1, wherein when a case in which the detecting result is not above the reference value is repeated a plurality of times, the discriminating means resets the reference value so as to be smaller than the reference value set at the last time.

6. The image forming apparatus according to claim 1, wherein in a case in which the detecting result is not above the reference value, the discriminating means resets a value obtained by subtracting a predetermined value from the reference value as the reference value.

7. The image forming apparatus according to claim 1, wherein the detecting portion detects the current flowing through the transfer member, and
wherein when a maximum current value is defined as Imax, a minimum current value is defined as Imin and a predetermined value is defined as an integer 2 or more, the discriminating means resets the reference value in a case in which a following relationship is satisfied:
Imax≥Imin×predetermined value.

8. The image forming apparatus according to claim 2, wherein the moving portion includes a cam member which rotates, and
wherein the discriminating means acquires a plurality of the values of current flowing through the transfer member detected by the detecting portion during one full rotation of the cam member and acquires the maximum current value and the minimum current value.

9. The image forming apparatus according to claim 1, wherein the applying portion applies a voltage of a smaller value as an absolute moisture content is greater while detecting of the detecting portion.

10. The image forming apparatus according to claim 1, wherein the discriminating means discriminates that the transfer member is in the separated position when a first time is elapsed from a timing when the detecting result of the detecting portion is below the reference value and discriminates that the transfer member is in the contact position when a second time is elapsed from a timing when the detecting result of the detecting portion is above the reference value.

11. The image forming apparatus according to claim 1, wherein the discriminating means informs an abnormality of the moving portion in a case in which a number of times when the detecting result detected by the detecting portion is not below the reference value while the moving operation of the moving portion is performed exceeds a predetermined number.
